(19) United States
(12) Patent Application Publication
(10) Pub. No.: US 2001/0045297 A1
(43) Pub. Date: Nov. 29, 2001

(54) Molding of electrical devices with a thermally conductive and electrically insulative polymer composition

(76) Inventors: James D. Miller, Marietta, GA (US); Kevin A. McCullough, Warwick, RI (US)

Correspondence Address: BARLOW, JOSEPHS & HOLMES, LTD., 101 DYER STREET, 5TH FLOOR, PROVIDENCE, RI, 02903, US

(21) Appl. No.: 09/774,520

(22) Filed: Jan. 31, 2001

Related U.S. Application Data
(60) Provisional application No. 60/179,637, filed on Feb. 1, 2000.

(51) Int. Cl. H01L 23/28; H05K 5/06; H01L 23/02

(52) U.S. Cl. 174/52.2; 174/52.4

(57) ABSTRACT

The present invention provides an overmolded electronic device cover assembly and method of manufacturing the same. The device cover assembly is molded directly over an electronic device, such as a resistor or a capacitor, that requires both electrical isolation and effective cooling. The device cover assembly is overmolded about and in direct contact with the electronic device package and is formed from a thermally conductive and electrically insulative moldable polymer composition. The molded device cover assembly is positioned in thermal communication with at least the front side, the rear side, the left side, the right side and the top side of the electronic device package for cooling thereof while providing electrical isolation and sealing the device against the effects of dust and moisture infiltration. The direct molding of the device cover assembly to the heat generating device obviates the need for interface materials, adhesives and other assembly operations.

### BACKGROUND OF THE INVENTION

The present invention relates generally to electronic solid-state components. More specifically, the present invention relates to a new construction for dissipating the operational heat generated while providing electrical isolation for such devices.

In the electronics and computer industries, it has been well known to employ various types of electronic device packages, such as capacitors, transistors and resistors. These device packages consist of a working element housed within the device package and wire leads running from the working element to the outside of the device package for connection into and electrical circuit. These device packages, particularly resistor devices, generate a great deal of heat during operation, which must be removed to prevent adverse effects or even failure of the device and the system into which the device is installed. For example, a 1000-Ohm resistor in a 120 Volt circuit must dissipate over 14 Watts of energy during operation and, if installed in a densely packaged circuit board, is highly susceptible to overheating which could destroy the resistor itself or other components proximal to the resistor.

In addition to the resistor device discussed above, there are many other types of device packages which are commonly used in electrical equipment. Various types of capacitor and transistor packages are mounted to circuit boards in computers and portable electronics to assist in directing and controlling the flow of electricity throughout the electronic device and to protect the sensitive processor and memory microchips from receiving too much voltage or to provide a consistent flow of level clean electricity. Every electronic device manufactured today uses some or all of these components in some combination and as the manufacturers strive to make the electronic devices smaller, the efficient dissipation of heat becomes and even greater issue.

Currently, the present state of the art offers few alternatives for the manufacture of these device covers and none of them provide an effective cooling solution for the device package contained therein. One solution for enclosing these devices employs a metallic outer cover. The outer cover is fashioned from extruded aluminum, die-cast aluminum or copper and installed onto the device package in an additional assembly step. The drawbacks to using a metallic solution include an additional assembly step and the requirement for providing electric isolation between the metallic cover, the device package and the wire leads. Although a metallic cover is capable of dissipating a great deal of heat, as discussed above, it requires an additional electrical isolation layer between the device package and the metallic cover. This isolation layer, although a good electrically insulative layer, is generally a poor thermal conductor thus preventing effective heat conduction between the device package and the device cover. In addition, in the event of a failure in the electrical isolation layer, the entire surface of the device cover may become electrified.

Another solution in the prior art is the use of polymer plastics for constructing the device cover. This solution provides effective electrical isolation for the device package contained therein, but also provides poor thermal conductivity. Generally, plastic covers actually retain the heat generated by the device package causing the interior temperature of the device to rise dramatically. As the operating temperature rises unacceptable levels are quickly reached resulting in a breakdown of both the device cover and the device within. Some attempts in the prior art have been made to employ plastics that have a natural thermally conductive properties of approximately 1 W/m° K to provide a plastic device cover with some ability to dissipate heat while continuing to provide electrical isolation, but to be effective these covers had to be constructed with relatively large surface areas resulting in bulky and large device packages and only marginal heat dissipation properties. The use of plastic device covers is also therefore unacceptable for use with devices in compact modern electronics that require a stable operating temperature.

The final solution available in the prior art is the use of ceramic material for the device cover. The ceramic materials do effectively provide effective electrical isolation and allow thermal dissipation. To construct a device package using a ceramic cover however requires several additional fabrication steps. The device package must be first placed into the ceramic housing and affixed therein using an adhesive, then the housing must be sealed using some form of polymer resin to prevent moisture from entering the operational body of the device. Due to the additional fabrication steps required, the use of ceramics for device covers therefore is also undesirable.

The foregoing device cover assemblies of the prior art suffer from the disadvantages of having multiple components and the high cost associated therewith. These multiple component device cover assemblies typically include expensive machined or extruded heat conductive metal, such as aluminum. Other parts, such as adhesives, sealants or electrical isolation layers require separate machining and/or fabrication steps for production. Therefore, these assemblies and methods are completely inappropriate for most electronic device packages.

In view the foregoing, there is a demand for a device package cover assembly that obviates the need for adhesives, sealants, mechanical connection steps as well as the need for expensive machined metallic parts. There is also a demand for a device cover assembly that can be permanently provided onto an electronic device for electrical isolation of the interior working parts while providing cooling for dissipating the heat generated therein. There is also a demand for an injection moldable device cover assembly that can be net-shape overmolded on the device package to provide a superior interface between the electronic device to be cooled and the heat dissipating material itself while providing electrical isolation for the device.

### SUMMARY OF THE INVENTION

The present invention preserves the advantages found in the prior art device cover assemblies for electrical circuit devices, such as resistors. In addition, it provides new advantages not found in currently available assemblies and overcomes many disadvantages of such currently available assemblies.

The invention is generally directed to a novel and unique overmolded heat dissipating cover assembly employing a previously unknown polymer composition that provides both heat dissipation and electrical insulation properties that have particular application in cooling electronic circuit devices, such as resistor, capacitor and transistor packages. The device cover assembly and method of the present invention enables the cost-effective cooling of electronic devices while realizing superior thermal conductivity and electrical isolation.

In accordance with the present invention, the device cover assembly is molded directly over an electronic device package to be cooled. The device cover includes heat-dissipating surfaces, to further enhance thermal conductivity of the assembly. The device cover assembly is overmolded about and in direct contact with the electronic device package contained therein and is formed from a thermally conductive moldable polymer composition. The direct over molding provides the additional advantage of sealing the device to prevent exposure to dust and moisture that may cause malfunction while also providing a completely unitary enclosure to effect electrical isolation. The molded heat sink assembly is positioned in thermal communication with at least the front side, the rear side, the left side, the right side and the topside of the electronic device package for cooling thereof. The direct molding of the heat sink assembly to the heat-generating device obviates the need for adhesive materials, electrical isolation layers and other mechanical structures, such as machined metallic or ceramic parts, for providing an enclosure and protection of the heat-generating device.

In the method of manufacture of the present invention, the electronic device is inserted into the molding cavity and the casing is net shape molded to form the entire device package. Net shape molding means that when the device is removed from the mold it is in its final shape ready for use and no further assembly or machining steps are required prior to incorporating the device in the finished product.

It is therefore an object of the present invention to provide a device cover assembly completely molded over a heat generating electronic device to be cooled.

It is an object of the present invention to provide a complete device cover assembly that encompasses a heat generating electronic device without the need for additional adhesives or assembly steps.

It is a further object of the present invention to provide a complete device cover assembly that is in thermal communication with the heat generating electronic device to provide effective heat dissipation while providing electrical isolation.

It is a further object of the present invention to provide a device cover assembly that can be easily molded over a heat generating electronic device without disturbing the device itself while, simultaneously, protecting the device from dust and moisture, providing electrical isolation and providing superior heat dissipation therefrom.

### BRIEF DESCRIPTION OF THE DRAWINGS

The novel features which are characteristic of the present invention are set forth in the appended claims. However, the invention's preferred embodiments, together with further objects and attendant advantages, will be best understood by reference to the following detailed description taken in connection with the accompanying drawings in which:

FIG. 1 is an perspective view of the device cover and electronic package assembly of the present invention;

FIG. 2 is a top view of the device cover and electronic package of the present invention of FIG. 1;

FIG. 3 is a cross sectional view of the electronic device along line 3-3 of FIG. 1; and

FIG. 4 is a perspective view of an alternative embodiment of the present invention.

### DETAILED DESCRIPTION OF THE PREFERRED EMBODIMENT

The present invention provides an enclosed electronic device package 10 (shown here as a resistor for illustration purposes only) for attachment to a wide range of types of electronic devics 12. These devices 12 may or may not be attached to a circuit board such as a motherboard or daughter card (not shown). The present invention is shown in the Figures, as having two wire leads for attaching to a circuit board or a semiconductor device 12 and this example is for illustration purposes only. It should be understood that various other types of electronic devices might be installed on a circuit board and accommodated by the present invention. For example, the present invention may accommodate capacitor devices as well as transistor devices.

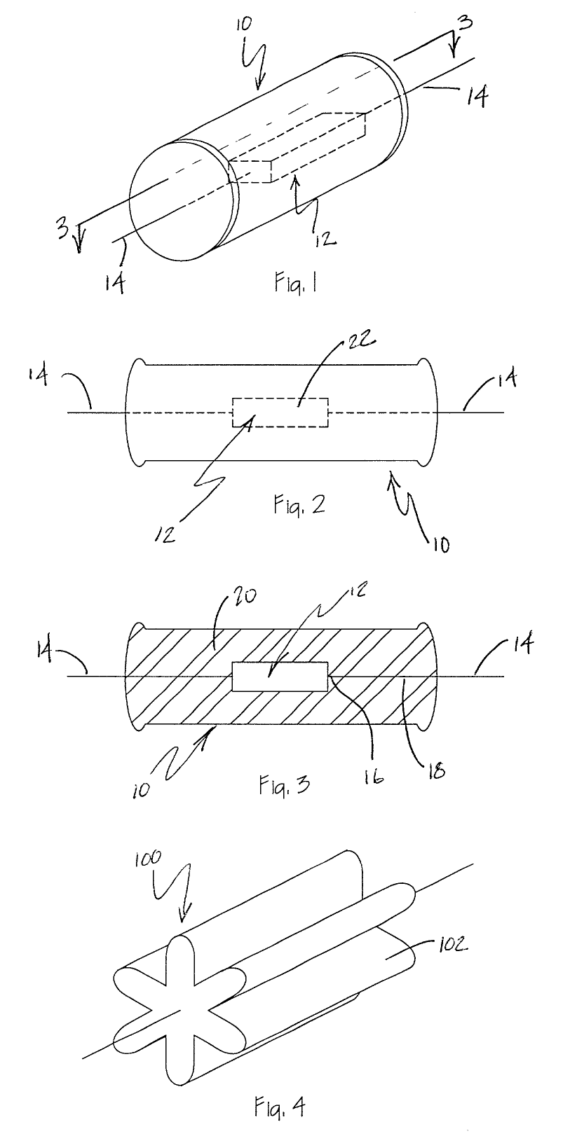

Referring first to FIGS. 1, 2 and 3, the encapsulated device package 10 of the present invention is shown installed over an electric resistor load device 12 with a two leads 14 emanating outwardly therefrom. The device cover assembly 10 is formed of a moldable material, such as a thermally conductive and electrically insulative polymer composition. For example, this composition is preferably a liquid crystal polymer with carbon fiber filler therein but may be made of other materials. As seen in FIG. 2 and FIG. 3, the thermally conductive and electrically insulative polymer composition is molded directly around the electronic device 12 to substantially embrace it and seal it on all of its sides. As can be seen in the figures, the device cover assembly 10 is molded about electronic device 12 without interfering with the critical leads 14 emanating from the electronic device 12 while effectively sealing the electronic device 12 from exposure to dust and moisture. By complete over molding of the device cover assembly 10 around the electronic device 12 and the emanation point 16 and upper portion 18 of the leads 14 can be carried out to provide an effective hermetic seal providing both environmental protection and electronic isolation for the electronic device 12 contained therein. However, since the polymer composition 20 is also thermally conductive and in complete thermal communication with the electronic device 12, effective heat dissipation is provided under the present invention.

Referring now to FIG. 3, the electronic device 12 to be overmolded by the device cover assembly 10 of the present invention is shown in detail. As stated above, this electronic device 12 is shown as a resistor for illustration purposes only. In this particular electronic device 12, the electronic device 12 is provided with at least two electronic interconnection leads 14 emanating therefrom. In accordance with the present invention, the moldable material 20 of the device cover assembly 10 of the present invention is formed and molded into direct contact with electronic device 12 to ensure superior heat dissipation therefrom.

In accordance with the present invention, the moldable material 20 of the device cover assembly 10 of the present invention is formed and molded into direct contact with the electronic device 12. The moldable material 20 is preferably a polymer base matrix filled with high aspect ratio carbon fiber filler. This moldable composition 20 has thermally conductive properties while also being di-electric, providing electrical isolation for the electronic device 12 contained therein. The natural properties of a moldable polymer formed in accordance with the present invention provide a high level of thermal conductivity while retaining the desirable electrically insulative properties of the polymer base matrix. In accordance with the present invention the integrally overmolded device cover assembly 10 provides an integrated solution for both protecting and electrically isolating the electronic device 12 contained therein while also providing effective heat dissipation.

The over molding process of the present invention is accomplished through an insert molding process as is well known in the art. The electrical device 12 is placed into the cavity of an injection-molding die (not shown), allowing the wire device leads 14 to protrude from the mold cavity. Once the electrical device 12 is inserted in the mold cavity, the cavity is flooded with a prepared polymer composite 20 of polymer base matrix and carbon fiber filler. Since the present invention is net shape molded, once the device cover assembly 10 is removed from the mold, it is in final net shape form for subsequent assembly into the finished product without any subsequent assembly or machining steps.

Turning to FIG. 4 an alternative embodiment 100 of the electronic device cover of the present invention is shown. Additional integrated heat dissipating members 102 are provided to further enhance the thermal conductivity of the device cover assembly 100 of the present invention. For example, the heat dissipating members 102 are shown to be fins for this particular application. It should be understood that these heat-dissipating members 102 might be pins or other configurations to suit the application at hand. It should also be noted that the heat dissipating members 102 extend so as to surround an electronic device (not shown) embedded in the device cover assembly 100. Depending on application, thermally conductive material and desired heat dissipation, the direction of these heat-dissipating members 102 can be varied. .

The present invention has a wide range of applications and can be easily adapted for such applications. Further applications include any circuit board configuration where an electrical device package is provided on a circuit board or similar substrate. The present invention may be easily adapted to an application where the circuit board containing the heat-generating device is completely encased in a housing, such as a Pentium II chip configuration. In this arrangement (not shown), the overmolded heat sink assembly may be molded directly over the housing of the heat-generating device, allowing the interim step of providing a plastic case over the device to be eliminated.

It is preferred that the present invention be manufactured from a unitary molded member of a thermally conductive and electrically insulative polymer or the like. For example, a polymer base matrix loaded with conductive filler material, such as carbon fiber, may be employed as the material for the present invention. Such unitary construction and direct over molding on a heat generating object is unlike that found in the prior and provides significant advantages including low cost, ease of manufacture and flexibility of heat geometry due to the ability to mold the assembly as opposed to machining it, while also providing electrical isolation.

It would be appreciated by those skilled in the art that various changes and modifications can be made to the illustrated embodiments without departing from the spirit of the present invention. All such modifications and changes are intended to be covered by the appended claims.

What is claimed is:

1. An electronic device package, comprising:
an electronic device having a front side, a rear side, a left side, a right side, bottom side and a top side;
at least two leads emanating from said electronic device package; and
a molded device cover disposed about said electronic device and in thermal communication with at least said front side, said rear side, said left side, said right side and said top side of said electronic device package.

2. The electronic device package of claim 1, wherein said molded device cover is made of thermally conductive, electrically insulative polymer material.

3. The electronic device package of claim 1, wherein said electronic device package is net-shape molded from a polymer base matrix loaded with a thermally conductive filler.

4. The electronic device package of claim 3, wherein said thermally conductive filler is carbon fiber.

5. The electronic device package of claim 1, wherein said molded device cover has a thermal conductivity of at least 20 W/m° K.

6. The electronic device package of claim 3, wherein said molded device cover has a thermal conductivity of at least 20 W/m° K.

7. An electronic device package, comprising:
an electronic device having a front side, a rear side, a left side, a right side, bottom side and a top side;
at least two leads emanating from said electronic device; and
a device cover assembly disposed about said electronic device package and in thermal communication with at least said front side, said rear side, said left side, said right side and said top side of said electronic device package; said device cover assembly being net shape molded of a thermally conductive, electrically insulative polymer composition.

8. The electronic device package of claim 7 wherein said thermally conductive, electrically insulative polymer composition is a polymer base matrix loaded with carbon fiber filler.

9. The electronic device package of claim 8, wherein said device cover assembly has a thermal conductivity of at least 20 W/m° K.

10. A method of manufacturing an electronic device package with integrated thermal dissipation and electrical isolation capabilities, comprising:
providing an electronic device having a front side, a rear side, a left side, a right side, bottom side and a top side;
providing at least two leads emanating from said electronic device package; and
over molding a device cover assembly of thermally conductive and electrically insulative polymer composition about and in direct contact with said electronic device package and in thermal communication with at least said front side, said rear side, said left side, said right side and said top side of said electronic device.

11. The method of manufacturing an electronic device package of claim 10, wherein said step of over molding a device cover assembly of thermally conductive and electrically insulative polymer composition further comprises a polymer base matrix loaded with a thermally conductive filler.

12. The method of manufacturing an electronic device package of claim 11, wherein said thermally conductive filler is carbon fiber.
